(19) United States
(12) Patent Application Publication
(10) Pub. No.: US 2024/0145303 A1
(43) Pub. Date: May 2, 2024

(54) SELECTIVE THIN FILM FORMATION METHOD AND METHOD OF MANUFACTURING SEMICONDUCTOR DEVICE USING THE SAME

(71) Applicant: SAMSUNG ELECTRONICS CO., LTD., Suwon-si (KR)

(72) Inventors: Sunhye HWANG, Suwon-si (KR); Hyeonggeun LIM, Suwon-si (KR); Byungkeun HWANG, Suwon-si (KR); Younjoung CHO, Suwon-si (KR)

(21) Appl. No.: 18/378,369

(22) Filed: Oct. 10, 2023

(30) Foreign Application Priority Data
Oct. 11, 2022 (KR) 10-2022-0129790
Sep. 4, 2023 (KR) 10-2023-0117217

(51) Int. Cl. H01L 21/768; H01L 21/02; H01L 21/321

(52) U.S. Cl. CPC H01L 21/76883; H01L 21/02211; H01L 21/0228; H01L 21/321

(57) ABSTRACT

A selective thin film formation method, comprising forming a structure on a substrate in which a first material film including silicon atoms and oxygen atoms and a second material film different from the first material film are exposed, selectively forming an inhibitor liner only on an exposed surface of the first material film among the first material film and the second material film by applying a compound represented by XₘSi(NR¹R²)ₙ or (XₐR³)ₘSi(NR¹R²)ₙ to the structure, and selectively forming a third material film only on the exposed surface of the second material film among the first material film and the second material film. X is a halogen atom, R¹, R², and R³ are each independently an alkyl group, an alkenyl group, an allyl group, or a heterocyclic group, a, m, and n are each independently an integer of 1 to 3, and m+n=4.

### CROSS-REFERENCE TO RELATED APPLICATION

Korean Patent Application No. 10-2022-0129790, filed on Oct. 11, 2022, and Korean Patent Application No. 10-2023-0117217 filed on, Sep. 4, 2023, in the Korean Intellectual Property Office, are incorporated by reference herein in their entirety.

### BACKGROUND

### 1. Field

Embodiments relate to a selective thin film formation method and a method of manufacturing a semiconductor device using the same.

### 2. Description of the Related Art

Due to the development of electronics technology, down-scaling of semiconductor devices is rapidly progressing in recent years, and accordingly, patterns constituting electronic devices have been miniaturized.

### SUMMARY

Embodiments are directed to a selective thin film formation method. The selective thin film formation method may include forming a structure on a substrate in which a first material film including silicon atoms and oxygen atoms and a second material film different from the first material film are exposed, selectively forming an inhibitor liner only on an exposed surface of the first material film among the first material film and the second material film by applying a compound represented by XₘSi(NR¹R²)ₙ or (XₐR³)ₘSi(NR¹R²)ₙ to the structure, and selectively forming a third material film only on the exposed surface of the second material film among the first material film and the second material film. X may be a halogen atom, R¹, R², and R³ may each independently be an alkyl group, an alkenyl group, an allyl group, or a heterocyclic group, a, m, and n may each independently be an integer of 1 to 3, and m plus n may equal 4.

Embodiments are also directed to a selective thin film formation method. The selective thin film formation method, may include selectively forming an inhibitor liner only on an exposed surface of the silicon oxide film by performing an atomic layer deposition process by applying a haloaminosilane precursor or an alkylaminosilane precursor to the structure, selectively forming an additional silicon nitride film only on an exposed surface of the silicon nitride film by performing an atomic layer deposition process, removing the inhibitor liner from the exposed surface of the silicon oxide film such that the thin film is selectively formed only on a desired material layer, and forming a structure in which a silicon oxide film and a silicon nitride film may be exposed.

Embodiments are also directed to a selective thin film formation method. The selective thin film formation method, may include forming a structure on a semiconductor substrate in which a first material film including silicon atoms and oxygen atoms and a second material film different from the first material film may be exposed, selectively forming an inhibitor liner only on an exposed surface of the first material film among the first material film and the second material film by applying a compound represented by XₘSi(NR¹R²)ₙ or (XₐR³)ₘSi(NR¹R²)ₙ to the structure, selectively forming a third material film only on the exposed surface of the second material film among the first material film and the second material film, and removing the inhibitor liner from the surface of the first material film in order to selectively form a predetermined material film only on a desired material film on a semiconductor substrate. X may be a halogen atom, R¹, R², and R³ may each independently be an alkyl group, an alkenyl group, an allyl group, or a heterocyclic group, a, m, and n may each independently be an integer of 1 to 3, and m plus n may equal 4.

Embodiments are also directed to a selective thin film formation method. The selective film formation method, may include forming a structure on a substrate in which a first material film including silicon atoms and oxygen atoms and a second material film different from the first material film may be exposed, selectively forming an inhibitor liner only on an exposed surface of the first material film among the first material film and the second material film by applying a compound represented by NR(SiX₃)₂ to the structure, and selectively forming a third material film only on an exposed surface of the second material film among the first material film and the second material film. X may be a halogen atom a carbon structure of an alkane, an alkene, an alkyne, or an allyl, an amine structure of NR¹R² where R¹ and R² may each independently be an alkane, an alkene, an allyl, or a heterocyclic carbon structure, or a mixed structure thereof, and R may be a methyl group, an ethyl group, or an alkyl group.

### BRIEF DESCRIPTION OF THE DRAWINGS

Features will become apparent to those of skill in the art by describing in detail exemplary embodiments with reference to the attached drawings in which:

FIG. 1 is a flowchart illustrating a selective thin film formation method according to an example embodiment.

FIGS. 2 to 5 are cross-sectional views of stages in a selective thin film formation method according to an example embodiment.

FIG. 6 is a flowchart illustrating a selective thin film formation method according to an example embodiment.

FIGS. 7 to 11 are cross-sectional views of stages in a selective thin film formation method according to an example embodiment.

### DETAILED DESCRIPTION

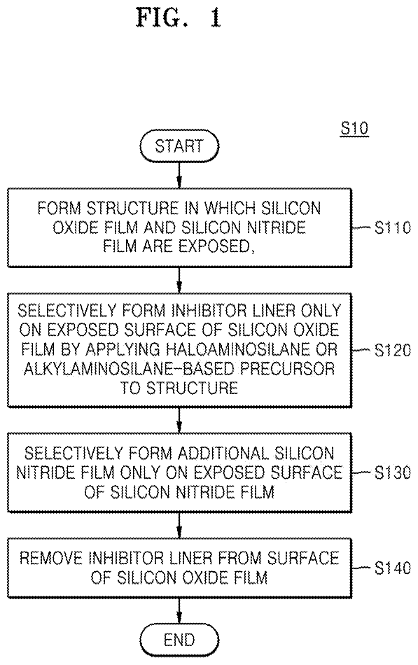

FIG. 1 is a flowchart illustrating a selective thin film formation method according to an example embodiment.

Referring to FIG. 1, the selective thin film formation method (S10) may include a process sequence of first to fourth operations (S110) to (S140).

A process order may be performed differently from the described order. In an implementation, two consecutively described processes may be performed substantially at the same time or performed in an order opposite to the described order.

The selective thin film formation method (S10) according to an example embodiment may include a first operation (S110) for forming a structure in which a silicon oxide film and a silicon nitride film are exposed, a second operation (S120) for selectively forming an inhibitor liner only on an exposed surface of the silicon oxide film by applying a haloaminosilane or alkylaminosilane-based precursor to the structure, a third operation (S130) of selectively forming an additional silicon nitride film only on an exposed surface of the silicon nitride film, and a fourth operation (S140) of removing the inhibitor liner from the surface of the silicon oxide film.

In the first operation (S110), a structure in which the silicon oxide film including silicon atoms and oxygen atoms and a silicon nitride film including silicon atoms and nitrogen atoms are exposed may be formed on a substrate.

The substrate may include a semiconductor substrate. The substrate may include a semiconductor substrate and a lower structure on the semiconductor substrate. The lower structure may include various conductive regions, e.g., wiring layers, contact plugs, transistors, or the like, and insulating patterns insulating them from each other.

The silicon oxide film may include SiO₂, borosilicate glass (BSG), phosphosilicate glass (PSG), borophosphosilicate glass (BPSG), undoped silicate glass (USG), or tetraethylorthosilicate glass (TEOS). As used herein, the term “or” is not an exclusive term, e.g., “A or B” would include A, B, or A and B.

The silicon nitride film may include SiN, SiON, SiCON, SiBN, or SiCN. As used herein, the terms “SiN”, “SiON”, “SiCON”, “SiBN”, “SiCN”, etc. denote materials including elements denoted by each term, and are not chemical formulas showing stoichiometric relationships.

After forming the structure in the first operation (S110), the silicon oxide film may include a first surface exposing a hydroxyl group (—OH), and the silicon nitride film may include a second surface exposing an amine group (—NH₂).

In the second operation (S120), a haloaminosilane precursor or an alkylaminosilane precursor may be applied to the structure formed in the first operation (S110) to selectively form an inhibitor liner only on the first surface of the silicon oxide film which may be an exposed surface of the silicon oxide film among the silicon oxide film and the silicon nitride film.

The inhibitor liner may include silicon atoms and fluorine atoms that were included in haloaminosilane or alkylaminosilane-based precursors. Specifically, the inhibitor liner may be formed such that three fluorine atoms may form a covalent bond around the silicon atom, and one oxygen atom may form a covalent bond to the exposed surface of the silicon oxide film.

In an implementation, while the inhibitor liner is being formed according to the second operation (S120), an amine group (—NH₂) present on the second surface of the silicon nitride film may not react with the precursor.

In an implementation, the process of forming the inhibitor liner according to the second operation (S120) may be performed in a dry method. In an implementation, the inhibitor liner may be selectively formed only on the first surface of the silicon oxide film using an atomic layer deposition process using a haloaminosilane or an alkylaminosilane-based precursor as a raw material.

In the third operation (S130), a new thin film may be selectively formed only on the second surface of the silicon nitride film by using the inhibitor liner as a blocking layer (or mask layer). In an implementation, a silicon nitride film or polysilicon may be formed only on the second surface of the silicon nitride film.

In a fourth operation (S140), the inhibitor liner may be removed from the first surface of the silicon oxide film. The process of removing the inhibitor liner may be performed by a wet etching process or a dry etching process. The process of removing the inhibitor liner may be a removing process using an etching selectivity between a material constituting the newly formed thin film and a material constituting the inhibitor liner.

As semiconductor devices are miniaturized, there is a limit to patterning in a photo process using a photoresist. Accordingly, in order to implement a micronized semiconductor device structure by a manufacturing process other than a photo process, a bottom-up process, such as an area selective deposition process has been developed. The area selective deposition process is a process technology to selectively form a new thin film only on a portion of a surface where a new thin film is to be formed, and the importance of the area selective deposition is being highlighted, and recently, active research is being conducted.

There are many types of thin films that require selectivity in the microstructure of semiconductor devices. The area selective deposition technology is required only on a desired surface on various surfaces, such as selectivity between a metal thin film and an insulating thin film, selectivity between a metal oxide thin film and an insulating thin film, selectivity between an insulating thin film and another insulating thin film, and selectivity between an insulating thin film and a silicon thin film.

In an implementation, the area selective deposition process is a technology for forming an inhibitor liner on the first surface where no new thin film is desired to be formed to passivate the first surface, and forming a new thin film only on the second surface where a new thin film is desired to be formed. In this case, when the new thin film to be formed is a thin film including silicon (e.g., silicon nitride film, polysilicon, or the like), the formation temperature may generally be about 400° C. or higher to satisfy the quality of a thin film applicable to semiconductor devices.

Therefore, while a new thin film is formed, the inhibitor liner may maintain a strong bond with the first surface without being decomposed at a high temperature of about 400° C. or higher. A material that is capable of maintaining the inhibitor liner without degrading or being removed in a high temperature process may be utilized.

The selective thin film formation method (S10) according to an example embodiment may provide a precursor material that selectively enables the deposition of a silicon-including thin film between an insulating thin film and another insulating thin film and between an insulating thin film and a silicon thin film.

In the selective thin film formation method (S10) according to an example embodiment, after an inhibitor liner is formed, the inhibitor liner may not decompose even at a high temperature of about 400° C. or higher, and an environment in which a new thin film to be formed on the second surface with high quality may be provided.

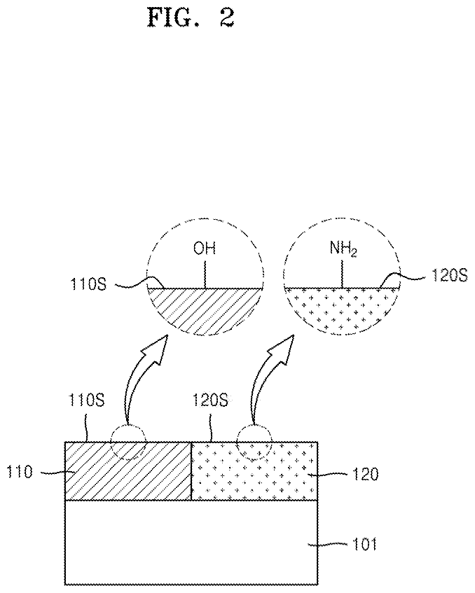

FIGS. 2 to 5 are cross-sectional views of stages in a selective thin film formation method according to an example embodiment.

Referring to FIG. 2, a structure in which a first material film 110 and a second material film 120 are exposed may be formed on the substrate 101.

The substrate 101 may be a wafer including silicon. In an implementation, the substrate 101 may be a wafer including a semiconductor element such as germanium, or a compound semiconductor such as silicon carbide (SiC), gallium arsenide (GaAs), indium arsenide (InAs), or indium phosphide (InP). The substrate 101 may have a silicon on insulator (SOI) structure. In an implementation, the substrate 101 may include a conductive region, e.g., a well doped with an impurity or a structure doped with an impurity therein.

In an implementation, the first material film 110 may include a silicon oxide film, and the second material film 120 may include a silicon nitride film. The first material film 110 may have include a first surface 1105 at which a hydroxyl group (—OH) is exposed, and the second material film 120 may include a second surface 120S at which an amine group (—NH₂) is exposed.

Each of the first material film 110 and the second material film 120 may be formed by using a physical vapor deposition process, a chemical vapor deposition process, or an atomic layer deposition process.

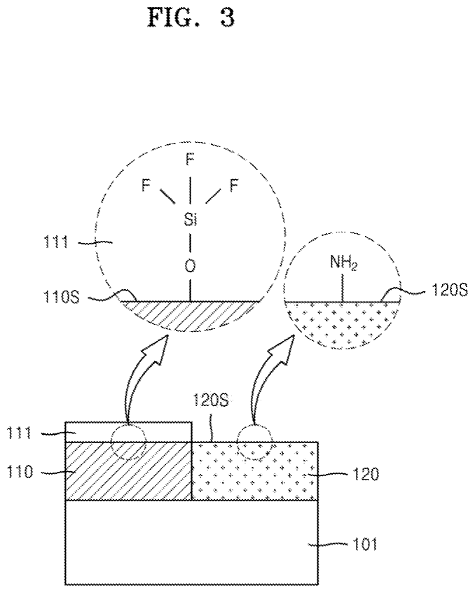

Referring to FIG. 3, a haloaminosilane or alkylaminosilane precursor may be applied onto the substrate 101 to selectively form an inhibitor liner 111 only on the first surface 1105 of the first material film 110 among the first surface 1105 of the first material film 110 and the second surface 120S of the second material film 120.

As will be described in detail below, in example embodiments, the inhibitor liner 111 may not be formed on the second surface 120S of the second material film 120 due to the selective chemical bonding of the precursor.

In an implementation, as illustrated in the drawings, the haloaminosilane or alkylaminosilane precursors may include trifluorodimethylsilanamine. Using the precursor, the inhibitor liner 111 may be formed only on the first surface 110S of the first material film 110.

The process of forming the inhibitor liner 111 may be performed by using an atomic layer deposition process. In an implementation, the inhibitor liner 111 may be selectively formed only on the first surface 110S of the first material film 110 by performing an atomic layer deposition process using a process gas including a precursor of trifluorodimethylsilaneamine as a raw material. In an implementation, due to the characteristics of an atomic layer deposition process, the inhibitor liner 111 may be formed as a monolayer.

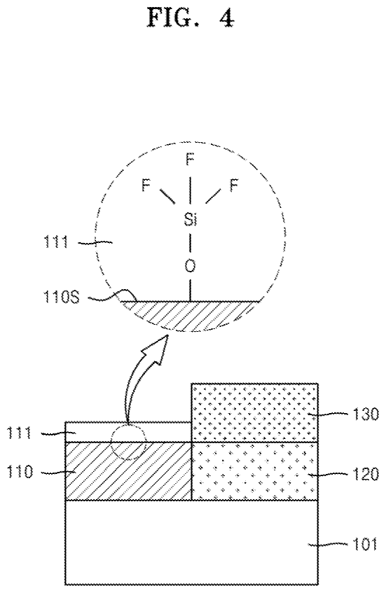

Referring to FIG. 4, the third material film 130 may be selectively formed only on the second surface 120S of the second material film 120 by using the inhibitor liner 111 as a blocking layer.

The newly formed third material film 130 may include, e.g., a silicon nitride film or polysilicon. The process of forming the third material film 130 may be performed as an atomic layer deposition process. In an implementation, the third material film 130 may be selectively formed only on the second surface 120S of the second material film 120 by performing a supercycle of an atomic layer deposition process.

The third material film 130 may be a thin film including silicon, and the formation temperature of the third material film 130 may generally be about 400° C. or higher to satisfy the quality of the thin film applicable to semiconductor devices. In this way, in a high-temperature process of about 400° C. or higher to form the third material film 130, the inhibitor liner 111 may not be decomposed and may maintain a strong bond with the first surface 110S of the first material film 110. In an implementation, the inhibitor liner 111 may not decompose even at a process temperature of from room temperature to about 400° C.

As will be described in detail below, the inhibitor liner 111 may not be decomposed in a high-temperature process of about 400° C. or higher due to the strong bonding energy between silicon atoms and fluorine atoms (Si—F).

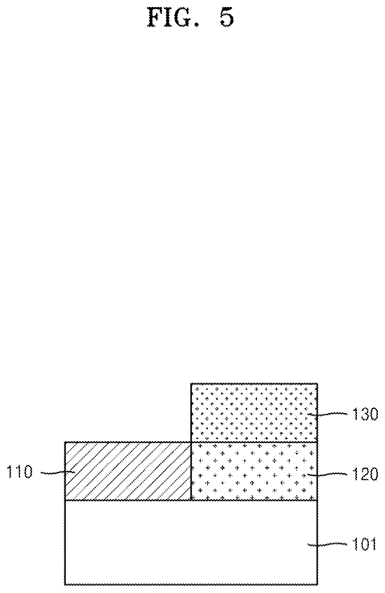

Referring to FIG. 5, after forming the third material film 130, the inhibitor liner 111 (refer to FIG. 4) may be removed from the first surface 110S of the first material film 110.

The process of removing the inhibitor liner 111 (refer to FIG. 4) may be performed by using a wet etching process or a dry etching process. In an implementation, the process of removing the inhibitor liner 111 (refer to FIG. 4) may be a removing process by using an etching selectivity between a material constituting the third material film 130 and a material constituting the inhibitor liner 111 (refer to FIG. 4).

In this way, through the selective thin film formation method, a desired thin film may be formed only on a desired material layer without using a photo process.

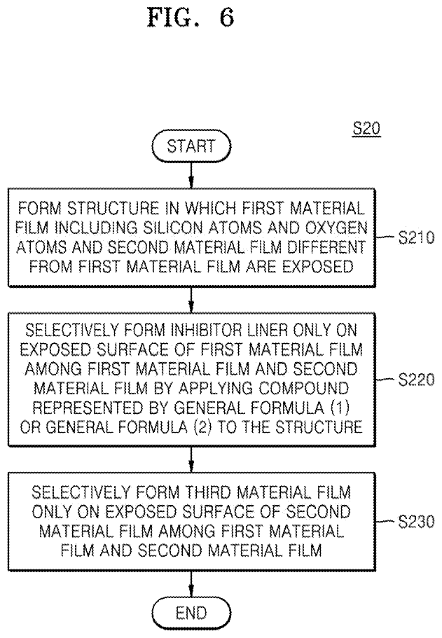

FIG. 6 is a flowchart illustrating a selective thin film formation method (S20) according to an example embodiment.

Referring to FIG. 6, the selective thin film formation method (S20) may include a process sequence of first to third operations (S210 to S230).

The selective thin film formation method (S20) according to an example embodiment may include a first operation (S210) of forming a structure in which a first material film including silicon atoms and oxygen atoms and a second material film different from the first material film are exposed on a substrate, a second operation (S220) of selectively forming an inhibitor liner only on an exposed surface of the first material film among the first material film and the second material film by applying a compound represented by XₘSi(NR¹R²)ₙ or (XₐR³)ₘSi(NR¹R²)ₙ to the structure, and a third operation (S230) of selectively forming a third material film only on the exposed surface of the second material film among the first material film and the second material film.

In the first operation (S210), a structure in which the first material film including silicon atoms and oxygen atoms and the second material film different from the first material film are exposed may be formed on the substrate.

The substrate may include a semiconductor substrate. The substrate may include a semiconductor substrate and a lower structure disposed on the semiconductor substrate. The lower structure may include various conductive regions, e.g., wiring layers, contact plugs, transistors, or the like, and insulating patterns insulating them from each other.

The first material film may include SiO₂, BSG, PSG, BPSG, USG, or TEOS.

The second material film may be a silicon-containing thin film or a metal-containing thin film. The silicon-containing thin film may be single crystal silicon, polysilicon, or a silicon nitride. The metal-containing thin film may be a metal or a metal oxide.

In an implementation, an operation of pre-treating the structure to expose a hydroxyl group (—OH) on the exposed surface of the first material film may further be included. In this case, the hydroxyl group (—OH) may not be exposed on the exposed surface of the second material film.

In the second operation (S220), a compound represented by XₘSi(NR¹R²)ₙ or (XₐR³)ₘSi(NR¹R²)ₙ may be applied to the structure.

In XₘSi(NR¹R²)ₙ or (XₐR³)ₘSi(NR¹R²)ₙ, X may represent a halogen atom, R¹, R², and R³ may represent each independently an alkyl group, an alkenyl group, an allyl group, or a heterocyclic group, and a, m, and n may represent each independently an integer of 1 to 3, and m plus n may equal four.

In the second operation (S220), an inhibitor liner may be selectively formed only on the exposed surface of the first material film among the first material film and the second material film. In an implementation, an unshared electron pair of the hydroxyl group (—OH) may react with the silicon atom of XₘSi(NR¹R²)ₙ or (XₐR³)ₘSi(NR¹R²)ₙ, thus, an amine group may leave from XₘSi(NR¹R²)ₙ or (XₐR³)ₘSi(NR¹R²)ₙ. In an implementation, the inhibitor liner may be formed by combining XₘSi(NR¹R²)ₙ or (XₐR³)ₘSi(NR¹R²)ₙ from which the amine group has been separated and the hydroxyl group (—OH) from which the unshared electron pair has been separated.

In an implementation, while the inhibitor liner is being formed in the second operation (S220), a functional group including unshared electron pairs may not be distributed on the exposed surface of the second material film, and a compound of XₘSi(NR¹R²)ₙ or (XₐR³)ₘSi(NR¹R²)ₙ may not react with the functional group.

In an implementation, the process of forming the inhibitor liner according to the second operation (S220) may be performed in a dry method. In an implementation, the inhibitor liner may be selectively formed only on the first surface of the first material film by performing an atomic layer deposition process using a compound of XₘSi(NR¹R²)ₙ or (XₐR³)ₘSi(NR¹R²)ₙ as a raw material.

In the third operation (S230), a new third material film may be selectively formed only on the second surface of the second material film by using the inhibitor liner as a blocking layer. In an implementation, the third material film may include the same type of material including substantially the same atoms as the second material film.

The formation of the third material film may be performed by using an atomic layer deposition process at a process temperature in a range from about 400° C. to about 800° C. A thermal energy provided at a process temperature may be less than a binding energy between a silicon atom and a halogen atom in XₘSi(NR¹R²)ₙ or (XₐR³)ₘSi(NR¹R²)ₙ. Accordingly, the inhibitor liner may not be decomposed or detached from the first surface of the first material film.

In the selective thin film formation method (S20) according to an example embodiment, similarly to the selective thin film formation method (S10) described above, a compound of XₘSi(NR¹R²)ₙ or (XₐR³)ₘSi(NR¹R²)ₙ that allows an area selective deposition between an insulating thin film and an insulating thin film and between an insulating thin film and a silicon thin film may be provided.

In the selective thin film formation method (S20) according to an example embodiment, after a compound of XₘSi(NR¹R²)ₙ or (XₐR³)ₘSi(NR¹R²)ₙ forms an inhibitor liner on the first surface of the first material film, the inhibitor liner may not decompose at a process temperature in a range from about 400° C. to about 800° C., and a third material film formed on the second surface of the second material film may have an excellent quality.

In some other embodiments, in the selective thin film formation method (S20) according to an embodiment, similar to the above method, instead of XₘSi(NR¹R²)ₙ or (XₐR³)ₘSi(NR¹R²)ₙ as described in the second operation (S220), a compound represented by NR(SiX₃)₂ may be applied to the structure.

In NR(SiX₃)₂, X may represent a halogen atom; the carbon structure of an alkane, alkene, alkyne, or allyl; an amine structure of NR¹R² (where R¹ and R² may each independently be an alkane, alkene, allyl, or heterocyclic carbon structure); or a mixed structure thereof; and R may represent a methyl group, an ethyl group, or an alkyl group. NR(SiX₃)₂ may be expressed as the following Formula (A).

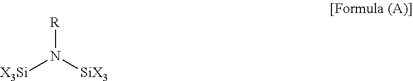

In the second operation S220, an inhibitor liner may be selectively formed only on an exposed surface of the first material film among the first material film and the second material film. In an implementation, the unshared electron pair of a hydroxy group (—OH) may react with each of the silicon atoms of NR(SiX₃)₂, and thus, all silane groups may be released from NR(SiX₃)₂. In an implementation, the inhibitor liner may be formed by bonding NR(SiX₃)₂ and the hydroxy group (—OH) in a state that all of the silane groups are released from NR(SiX₃)₂ and the unshared electron pair is released from the hydroxy group (—OH). In an implementation, two hydroxy groups (—OH) from which the unshared electron pair may be removed may bond to the location of NR(SiX₃)₂ where the two silane groups may be released.

Accordingly, while the inhibitor liner is formed during the second operation (S220), because functional groups including an unshared electron pair may not be distributed on the exposed surface of the second material film, the compound of NR(SiX₃)₂ may not react with the hydroxy group (—OH). The details of using the NR(SiX₃)₂ may be obvious to those skilled in the art based on the above description, and thus, the description thereof is omitted here.

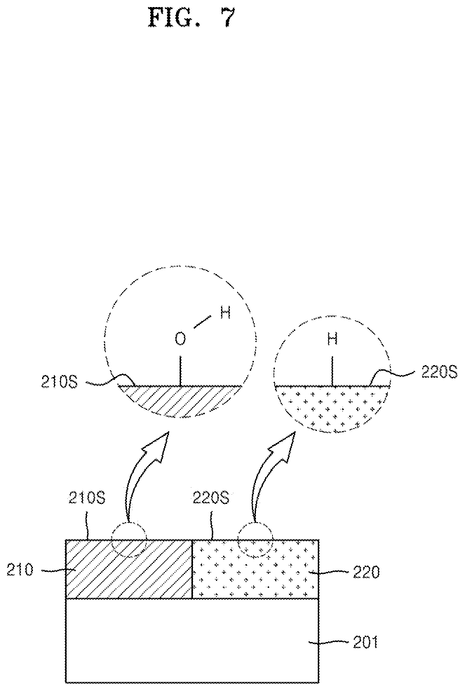

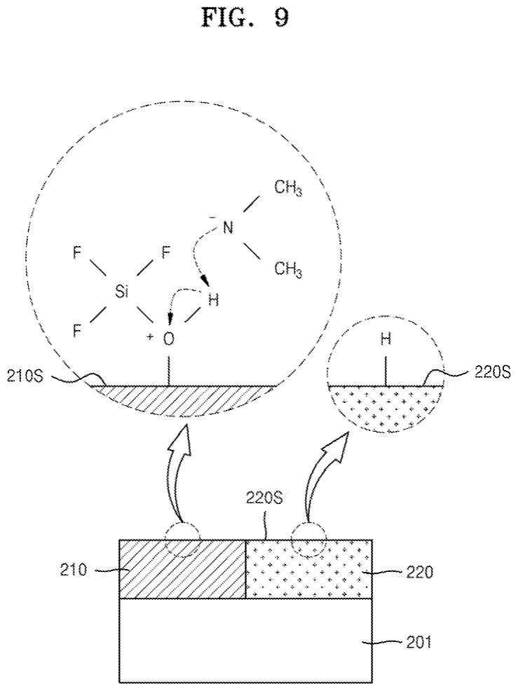

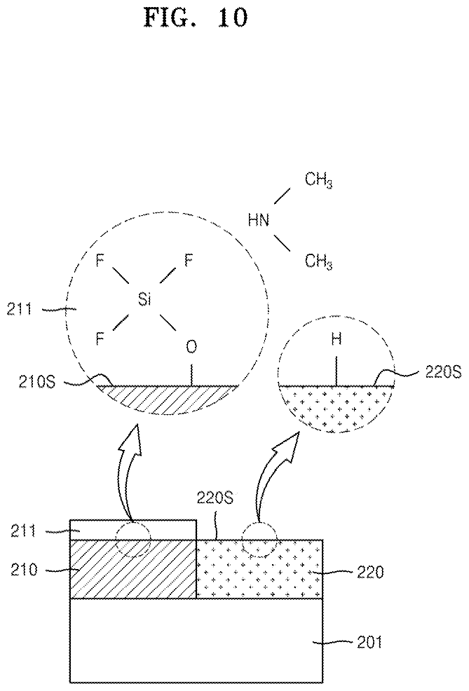

FIGS. 7 to 11 are cross-sectional views of stages in a selective thin film formation method according to an example embodiment.

Referring to FIG. 7, a structure in which a first material film 210 and a second material film 220 may be exposed may be formed on a substrate 201.

The substrate 201 may be a wafer including silicon. The substrate 201 may be substantially the same as the substrate 101 described above.

The first material film 210 may include a silicon oxide film, and the second material film 220 may include polysilicon. The first material film 210 may include a first surface 210S on or at which a hydroxyl group (—OH) may be exposed, and the second material film 220 may include a second surface 220S on or at which a hydrogen atom (—H) may be exposed.

The first material film 210 and the second material film 220 may be formed by using a physical vapor deposition process, a chemical vapor deposition process, or an atomic layer deposition process, respectively.

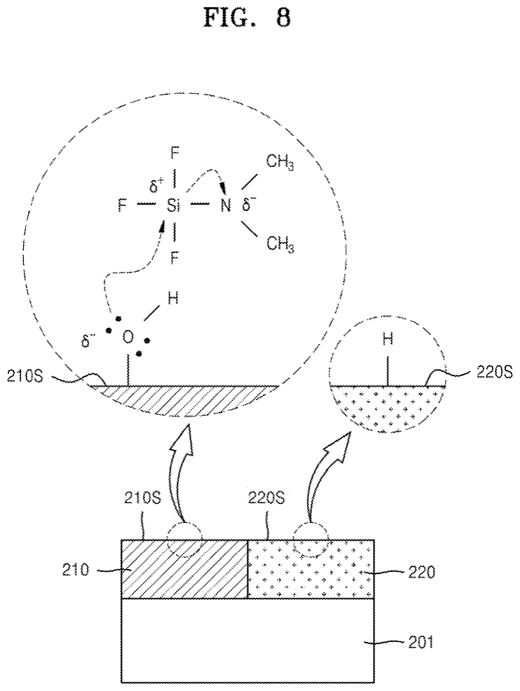

Referring to FIGS. 8 to 10 in sequence, a compound XₘSi(NR¹R²)ₙ or (XₐR³)ₘSi(NR¹R²)ₙ may be applied to the structure to selectively form an inhibitor liner 211 only on the first surface 210S of the first material film 210 among the first surface 210S of the first material film 210 and the second surfaces 220S of the material film 220.

In XₘSi(NR¹R²)ₙ or (XₐR³)ₘSi(NR¹R²)ₙ, X may represent a halogen atom, R¹, R², and R³ may represent each independently an alkyl group, an alkenyl group, an allyl group, or a heterocyclic group, and a, m, and n may represent each independently an integer of 1 to 3, and m plus n may equal four.

In an implementation, (XₐR³)ₘSi(NR¹R²)ₙ may have a structure in which X and (NR¹R²) are the same in XₘSi(NR¹R²)ₙ, and R³ is added. A halogen atom alone may be placed in X, or may be independently represented by a general formula of alkylhalogen.

In an implementation, a structure, such as guanidine, morpholine, indole, thiotrimethyl, or the like, or a structure that does not include a nitrogen atom may be applied to the (NR¹R²) position of XₘSi(NR¹R²)ₙ.

In an implementation, as illustrated in the drawings, trifluorodimethylsilaneamine may be used. The inhibitor liner 211 may be formed only on the first surface 210S of the first material film 210 using the precursor.

An unshared electron pair of an oxygen atom of the hydroxyl group (—OH) at the first surface 210S of the first material film 210 may attack or react with silicon of trifluorodimethylsilaneamine, and thus, a chemical reaction in which an amine group is separated as a leaving group may occur.

A hydrogen atom on the second surface 220S of the second material film 220 may not include an unshared electron pair unlike the oxygen atom, and a chemical reaction, like that between a hydroxyl group (—OH) and aminosilane on the first surface 210S of the first material film 210, may not occur. Due to the chemical reaction, trifluorodimethylsilaneamine may be selectively formed as the inhibitor liner 211 only on the first surface 210S of the first material film 210.

In this way, looking at the functional group on the first surface 210S of the first material film 210 which may be blocked by the inhibitor liner 211, it may be seen that the first surface 210S may include a surface terminated with fluorine atoms. The bond energy between a silicon atom and a fluorine atom (Si—F) may be greater than that between a silicon atom and a carbon atom (Si—C).

Accordingly, when trifluorodimethylsilaneamine is used, the inhibitor liner 211 according to an example embodiment may not decompose but may be maintained even at a higher process temperature than that of dimethylaminotrimethylsilane (DMATMS) having a bond (Si—C) between silicon atoms and carbon atoms.

When using DMATMS, a surface of a silicon oxide film may be blocked with DMATMS, and TiN may be formed in a layered structure of Ru, TiN, or TiO₂, the selectivity of the inhibitor liner may deteriorate at a temperature above about 300° C. Accordingly, DMATMS may be difficult to faithfully perform the function of an inhibitor liner, especially at high temperatures.

In an implementation, a selective thin film formation method in which the inhibitor liner 211 does not decompose at a process temperature in a range from about 400° C. to about 800° C. may be formed by manufacturing the inhibitor liner 211 so that a strong bond is formed between the silicon atom and the fluorine atom (Si—F) by using a compound of XₘSi(NR¹R²)ₙ or (XₐR³)ₘSi(NR¹R²)ₙ.

In an implementation, the inhibitor liner 211 may be formed on a surface of the silicon oxide film as a fluorine atom terminal group. In an implementation, in the case of using a precursor having a structure including a fluorine group, such as trifluorodimethylsilaneamine, the amine group may leave as a leaving group, and the surface of the silicon oxide film may be passivated with fluorine atoms.

In this case, the bonding dissociation energy between the silicon atom and the fluorine atom (Si—F) may be relatively strong at about 540 kJ/mol, and even if the formation temperature of the silicon-containing thin film (e.g., Si, SiN, SiCN, or the like) in a subsequent process is a high temperature in a range of about 400° C. to about 800° C., the inhibitor liner 211 may not be decomposed and may be maintained during the process of forming the selective thin film.

For reference, in alkylaminosilane, which may be used as an inhibitor liner, the bonding dissociation energy between a silicon atom and a carbon atom (Si—C) may be about 435 kJ/mol, which may be a relatively weaker bonding than the bonding between a silicon atom and a fluorine atom (Si—F). Accordingly, if an inhibitor liner is formed on a surface of a silicon oxide film as a carbon atom terminal group, when forming a silicon-including thin film (e.g., Si, SiN, SiCN, etc.) in a subsequent process, there could be a restriction on a process temperature.

A process of forming the inhibitor liner 211 according to an example embodiment may be performed by using an atomic layer deposition process. In an implementation, the inhibitor liner 211 may be selectively formed only on the first surface 210S of the first material film 210 by performing an atomic layer deposition process using a process gas including a compound of XₘSi(NR¹R²)ₙ or (XₐR³)ₘSi(NR¹R²)ₙ as a raw material. Therefore, due to the characteristics of the atomic layer deposition process, the inhibitor liner 211 may be formed as a monolayer.

In an implementation, a material used for the inhibitor liner 211 may be haloaminosilane. Among halogen atoms, the fluorine atom may have the strongest bonding force with the silicon atom, e.g., because it does not decompose even at a high temperature, a haloaminosilane including a fluorine group may be used.

A representative structure having a fluorine atom or a chlorine atom may be XₘSi(NR¹R²)ₙ. In an implementation, a chemical structure of a precursor may be represented by one of Formulas (1) to (6) below.

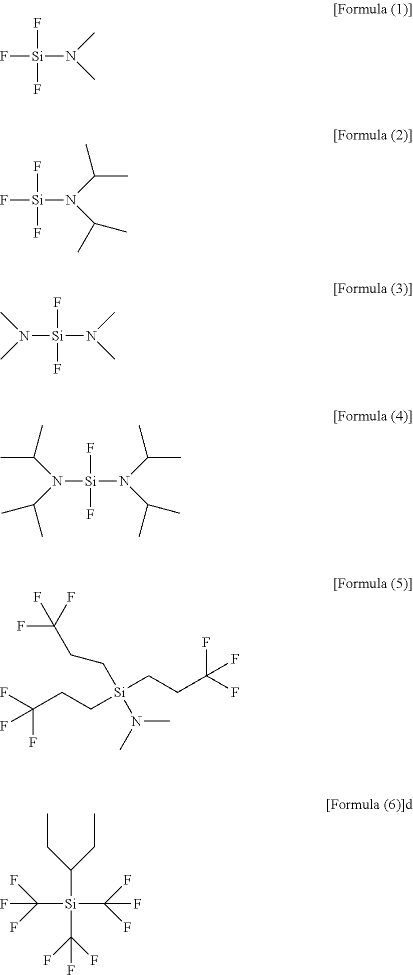

In an implementation, in Formulas (1) to (6), other atoms (or ligands) may be positioned in the place of the fluorine atom. Formulas (1) to (6) may include at least one fluorine atom.

The basis for determining that the above chemical structure is possible is based on the bond dissociation energy between the silicon atom and the nitrogen atom (Si—N) when one or two silicon atoms are bonded to dimethylamine confirmed by the simulation in the paper. A typical precursor structure of dimethylamine is DMATMS, and, a hydroxyl group (—OH) on a surface of a silicon oxide film may react with an amine group of DMATMS to be silylated.

The bond dissociation energy of Si—N(CH₃)₂ of the DMATMS may be about 100.3 kJ/mol, and the bond dissociation energy of Si—(N(CH₃)₂)₂ may be about 101.3 kJ/mol. Ligands having a similar value to the bond dissociation energy may react with a hydroxyl group (—OH) on a surface of a silicon oxide film.

In an implementation, although the present specification is typically described based on an amine group, the scope may be extended to ligands reacting with a hydroxyl group (—OH) in addition to an amine group. In an implementation, a chemical structure of a precursor may be represented by one of Formulas (7) to (14) as follows.

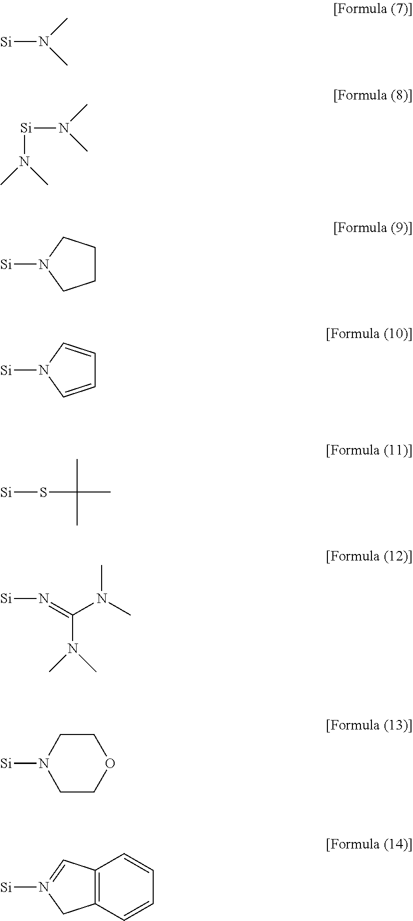

The inhibitor liner 211 may be implemented by an atomic layer deposition process using a precursor having structures of Formulas (7) to (14).

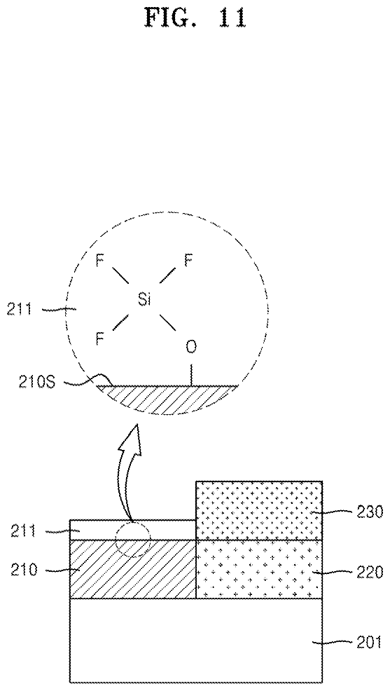

Referring to FIG. 11, a third material film 230 may be selectively formed only on the second surface 220S of the second material film 220 by using the inhibitor liner 211 as a blocking layer.

The third material film 230 may include, e.g., a silicon nitride film or polysilicon. The process of forming the third material film 230 may be performed by using an atomic layer deposition process. In an implementation, the third material film 230 may be selectively formed only on the second surface 220S of the second material film 220 by performing a supercycle of an atomic layer deposition process.

In an implementation, a silicon-containing thin film may be formed on the third

material film 230. In order to form the silicon-containing thin film, a silane material, such as monosilane, disilane, or trisilane may be used as a raw material. In an implementation, a halosilane material, e.g., monochlorosilane, dichlorosilane, trichlorosilane, tetrachlorodisilane, hexachlorodisilane, pentachlordisilane, trichlorodisilane, dichlorodisilane, monochlorodisilane, or chlorotrisilane, may be used as a raw material.

In an implementation, a silicon nitride film may be formed on the third material film 230. In order to form the silicon nitride film, an aminosilane or halosilane precursor and a nitrogen reactant (e.g., NH₃, N₂, N₂H₂, etc.) may be used together as raw materials.

In an implementation, a silicon carbonitride film may be formed on the third material film 230. In order to form the silicon carbonitride film, an alkylaminosilane or alkylhalosilane precursor and a nitrogen reactant (e.g., NH₃, N₂, N₂H₂, etc.) may be used together as raw materials.

The third material film 230 may be a thin film including silicon, and the formation temperature of the third material film 230 may generally be in a range from about 400° C. to about 800° C. to satisfy the quality of a thin film applicable to semiconductor devices. In this way, at a process temperature in a range of about 400° C. to about 800° C. for forming the third material film 230, the inhibitor liner 211 may not be decomposed and may maintain a strong bond with the first surface 210S of the first material film 210.

As described above, the inhibitor liner 211 may not be decomposed at a process temperature in a range of about 400° C. to about 800° C. due to the strong bonding energy of the bond between the silicon atom and the fluorine atom (Si—F). The bond between the silicon atom and the fluorine atom (Si—F) may not be decomposed even at a process temperature from room temperature to about 400° C.

In this way, through the selective thin film formation method according to an embodiment, a desired thin film may be formed only on a desired material film without using a photo process.

In an implementation, a silicon nitride film and polysilicon may be the second material films 120 and 220. In an implementation, the second material films 120 and 220 may be single crystal silicon, silicon oxycarbide, silicon oxynitride, or silicon oxyboride.

A silicon nitride film and polysilicon may be the third material films 130 and 230. In an implementation, the third material films 130 and 230 may be a metal or a metal oxide.

In a manufacturing process of a semiconductor device, an inhibitor liner may be formed only on a thin film including a material including silicon atoms and oxygen atoms on an exposed surface of a plurality of thin films including different materials from each other. Substantially the same may be applied to a method of manufacturing a semiconductor device capable of improving productivity and economy according to the formation of a selective thin film.

A semiconductor device may be a memory device or a logic device. The memory device may be, e.g., a volatile memory device, such as a Dynamic Random Access Memory (DRAM), a Static Random Access Memory (SRAM), a flash, Phase-change Random Access Memory (PRAM), a Magnetoresistive Random Access Memory (MRAM), a ferroelectric random access memory (FeRAM), or a resistive random access memory (RRAM).

By way of summation and review, a technology may be for selectively forming a new thin film only on some thin films including a specific material on a surface where a plurality of thin films including different materials are exposed in the process of manufacturing a semiconductor device.

According to an embodiment, a selective thin film formation method may be capable of improving productivity and economy according to the formation of a selective thin film by forming an inhibitor liner only on a thin film including a material including silicon atoms and oxygen atoms on an exposed surface of a plurality of thin films including different materials from each other.

According to another embodiment, there is provided a selective thin film formation method capable of improving productivity and economy according to the formation of a selective thin film by forming an inhibitor liner only on a thin film including a material including silicon atoms and oxygen atoms on an exposed surface of a plurality of thin films including different materials from each other in a manufacturing process of a semiconductor device.

One or more embodiments may provide a selective thin film formation method using an inhibitor liner.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A selective thin film formation method, comprising:
forming a structure on a substrate in which a first material film including silicon atoms and oxygen atoms and a second material film different from the first material film are exposed;
selectively forming an inhibitor liner only on an exposed surface of the first material film among the first material film and the second material film by applying a compound represented by XₘSi(NR¹R²)ₙ or (XₐR³)ₘSi(NR¹R²)ₙ to the structure; and
selectively forming a third material film only on the exposed surface of the second material film among the first material film and the second material film, wherein:
X is a halogen atom,
R¹, R², and R³ are each independently an alkyl group, an alkenyl group, an allyl group, or a heterocyclic group,
a, m, and n are each independently an integer of 1 to 3, and
m+n=4.

2. The selective thin film formation method as claimed in claim 1, wherein:
before the forming of the inhibitor liner, a hydroxyl group is distributed on the exposed surface of the first material film, and
a hydroxyl group is not distributed on an exposed surface of the second material film.

3. The selective thin film formation method as claimed in claim 2, wherein an unshared electron pair of the hydroxyl group reacts with the silicon atom of XₘSi(NR¹R²)ₙ or (XₐR³)ₘSi(NR¹R²)ₙ to leave an amine group from XₘSi(NR¹R²)ₙ or (XₐR³)ₘSi(NR¹R²)ₙ.

4. The selective thin film formation method as claimed in claim 3, wherein the inhibitor liner is formed by combining XₘSi(NR¹R²)ₙ or (XₐR³)ₘSi(NR¹R²)ₙ from which the amine group is separated and the hydroxyl group from which the unshared electron pair is separated.

5. The selective thin film formation method as claimed in claim 3, wherein a functional group including an unshared electron pair is not present on the exposed surface of the second material film.

6. The selective thin film formation method as claimed in claim 5, wherein the second material film includes single crystal silicon, polysilicon, a silicon nitride, a metal, or a metal oxide.

7. The selective thin film formation method as claimed in claim 1, wherein the third material film includes a same type of material including substantially same atoms as the second material film.

8. The selective thin film formation method as claimed in claim 1, wherein the forming of the third material is performed at a process temperature in a range of about 400° C. to about 800° C.

9. The selective thin film formation method as claimed in claim 8, wherein thermal energy provided in the process temperature is less than a bonding energy between the silicon atom and the halogen atom in XₘSi(NR¹R²)ₙ or (XₐR³)ₘSi(NR¹R²)ₙ.

10. The selective thin film formation method as claimed in claim 1, wherein X is fluorine.

11-15. (canceled)

16. A selective thin film formation method, comprising:
forming a structure on a semiconductor substrate in which a first material film including silicon atoms and oxygen atoms and a second material film different from the first material film are exposed;
selectively forming an inhibitor liner only on an exposed surface of the first material film among the first material film and the second material film by applying a compound represented by XₘSi(NR¹R²)ₙ or (XₐR³)ₘSi(NR¹R²)ₙ to the structure;
selectively forming a third material film only on the exposed surface of the second material film among the first material film and the second material film; and
removing the inhibitor liner from the surface of the first material film in order to selectively form a predetermined material film only on a desired material film on a semiconductor substrate, wherein:
X is a halogen atom,
R¹, R², and R³ are each independently an alkyl group, an alkenyl group, an allyl group, or a heterocyclic group,
a, m, and n are each independently an integer of 1 to 3, and
m+n=4.

17. The selective thin film formation method as claimed in claim 16, wherein forming the inhibitor liner includes:
distributing a hydroxyl group on the exposed surface of the first material film,
leaving an amine group from XₘSi(NR¹R²)ₙ or (XₐR³)ₘSi(NR¹R²)ₙ by reacting an unshared electron pair of the hydroxy group with the silicon atom of XₘSi(NR¹R²)ₙ or (XₐR³)ₘSi(NR¹R²)ₙ, and
bonding XₘSi(NR¹R²)ₙ or (XₐR³)ₘSi(NR¹R²)ₙ from which the amine group has been separated and the hydroxyl group from which the unshared electron pair is separated.

18. The selective thin film formation method as claimed in claim 16, wherein XₘSi(NR¹R²)ₙ or (XₐR³)ₘSi(NR¹R²)ₙ includes a haloaminosilane or a alkylaminosilane.

19. The selective thin film formation method as claimed in claim 16, wherein:
the second material film includes single crystal silicon, polysilicon, silicon nitride, silicon oxycarbide, silicon oxynitride, or silicon oxyboride, and
a hydroxyl group is not distributed on the exposed surface of the second material film.

20. The selective thin film formation method as claimed in claim 19, wherein:
the third material film includes a silicon nitride, polysilicon, a metal, or a metal oxide, and
the third material film is formed at a process temperature in a range of about 400° C. to about 800° C.

21. A selective thin film formation method, comprising:
forming a structure on a substrate in which a first material film including silicon atoms and oxygen atoms and a second material film different from the first material film are exposed;
selectively forming an inhibitor liner only on an exposed surface of the first material film among the first material film and the second material film by applying a compound represented by NR(SiX₃)₂ to the structure; and
selectively forming a third material film only on an exposed surface of the second material film among the first material film and the second material film,
wherein:
X is a halogen atom a carbon structure of an alkane, an alkene, an alkyne, or an allyl, an amine structure of NR¹R² where R¹ and R² are each independently an alkane, an alkene, an allyl, or a heterocyclic carbon structure, or a mixed structure thereof, and
R is a methyl group, an ethyl group, or an alkyl group.

22. The selective thin film formation method as claimed in claim 21, wherein:
before forming the inhibitor liner, a hydroxyl group is distributed on the exposed surface of the first material film, and
a hydroxyl group is not distributed on the exposed surface of the second material film.

23. The selective thin film formation method as claimed in claim 22, wherein an unshared electron pair of the hydroxyl group reacts with each silicon atom of NR(SiX₃)₂ to release all silane groups from NR(SiX₃)₂.

24. The selective thin film formation method as claimed in claim 23, wherein the inhibitor liner is formed by bonding NR(SiX₃)₂ from which all of the silane groups are released with the hydroxyl group from which the unshared electron pair is released.

25. The selective thin film formation method as claimed in claim 21, wherein the third material film includes the same type of material including substantially the same atoms as the second material film.
